(19) United States
(12) Patent Application Publication
(10) Pub. No.: US 2023/0411708 A1
(43) Pub. Date: Dec. 21, 2023

(54) BATTERY DEVICE

(71) Applicant: DENSO CORPORATION, Kariya-city (JP)

(72) Inventors: Yoshihiro SATO, Kariya-city (JP); Taisuke KURACHI, Kariya-city (JP); Shingo KAWAHARA, Kariya-city (JP)

(73) Assignee: DENSO CORPORATION, Kariya-city (JP)

(21) Appl. No.: 18/365,359

(22) Filed: Aug. 4, 2023

Related U.S. Application Data
(63) Continuation of application No. PCT/JP2022/004619, filed on Feb. 7, 2022.

(30) Foreign Application Priority Data
Mar. 23, 2021 (JP) 2021-049206

(51) Int. Cl. H01M 10/42; G01R 31/367; G01R 31/36; G01R 31/388; B60L 58/10

(52) U.S. Cl. CPC H01M 10/425; G01R 31/367; G01R 31/3648; H01M 2220/20; B60L 58/10; H01M 2010/4278; H01M 2010/4271; G01R 31/388

(57) ABSTRACT

A battery device includes: a storage unit that stores battery information including a closed circuit voltage of a plurality of battery cells electrically connected to each other and a change amount in the closed circuit voltage; a setting unit that sets an acquisition range of the closed circuit voltage based on the battery information; a detection unit that detects the closed circuit voltage; and a conversion unit that converts the closed circuit voltage detected by the detection unit into a digital signal within the acquisition range set by the setting unit.

### CROSS REFERENCE TO RELATED APPLICATIONS

The present application is a continuation application of International Patent Application No. PCT/JP2022/004619 filed on Feb. 7, 2022, which designated the U.S. and claims the benefit of priority from Japanese Patent Application No. 2021-049206 filed on Mar. 23, 2021. The entire disclosures of all of the above applications are incorporated herein by reference.

### TECHNICAL FIELD

The disclosure provided herein relates to a battery device.

### BACKGROUND

A conceivable technique teaches a capacity adjustment device that equalizes the SOCs of a plurality of lithium secondary batteries.

### SUMMARY

According to an example, a battery device may include: a storage unit that stores battery information including a closed circuit voltage of a plurality of battery cells electrically connected to each other and a change amount in the closed circuit voltage; a setting unit that sets an acquisition range of the closed circuit voltage based on the battery information; a detection unit that detects the closed circuit voltage; and a conversion unit that converts the closed circuit voltage detected by the detection unit into a digital signal within the acquisition range set by the setting unit.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a block diagram showing a battery device and an assembled battery;

FIG. 2 is a graph showing SOC and OCV characteristics;

FIG. 3 is a timing chart showing voltage detection;

FIG. 4 is a timing chart showing voltage detection;

FIG. 5 is a flowchart illustrating voltage detection process;

FIG. 6 is a flowchart illustrating voltage detection process; and

FIG. 7 is a timing chart showing voltage detection.

### DETAILED DESCRIPTION

The closed circuit voltage of lithium secondary batteries is used to equalize the SOCs of a plurality of lithium secondary batteries. Therefore, it is required to improve the detection accuracy of the closed circuit voltage.

An object of the present disclosure is to provide a battery device with improved detection accuracy of a closed circuit voltage.

A battery device according to an aspect of the present embodiments includes a storage unit that stores battery information including closed circuit voltages of a plurality of electrically connected battery cells and an amount of change in the closed circuit voltage;
a setting unit that sets an acquisition range of the closed circuit voltage based on the battery information; and
a detection unit that detects the closed circuit voltage; and
a conversion unit that converts the closed circuit voltage detected by the detection unit into a digital signal within the acquisition range set by the setting unit.

According to this, the detection accuracy of the closed circuit voltage is improved.

The reference numerals in parentheses above indicate only a correspondence relationship with the configuration described in the embodiment to be described later, and do not limit the technical range in any way.

The following will describe embodiments for carrying out the present disclosure with reference to the drawings. In each of embodiments, parts/configurations corresponding to the elements described in the preceding embodiments are denoted by the same reference numerals, and redundant explanation may be omitted. When only a part of a configuration is described in an embodiment, another preceding embodiment may be applied to the other parts of the configuration.

When, in each embodiment, it is specifically described that combination of parts is possible, the parts can be combined. In a case where any obstacle does not especially occur in combining the parts of the respective embodiments, it is possible to partially combine the embodiments, the embodiment and the modification, or the modifications even when it is not explicitly described that combination is possible.

### First Embodiment

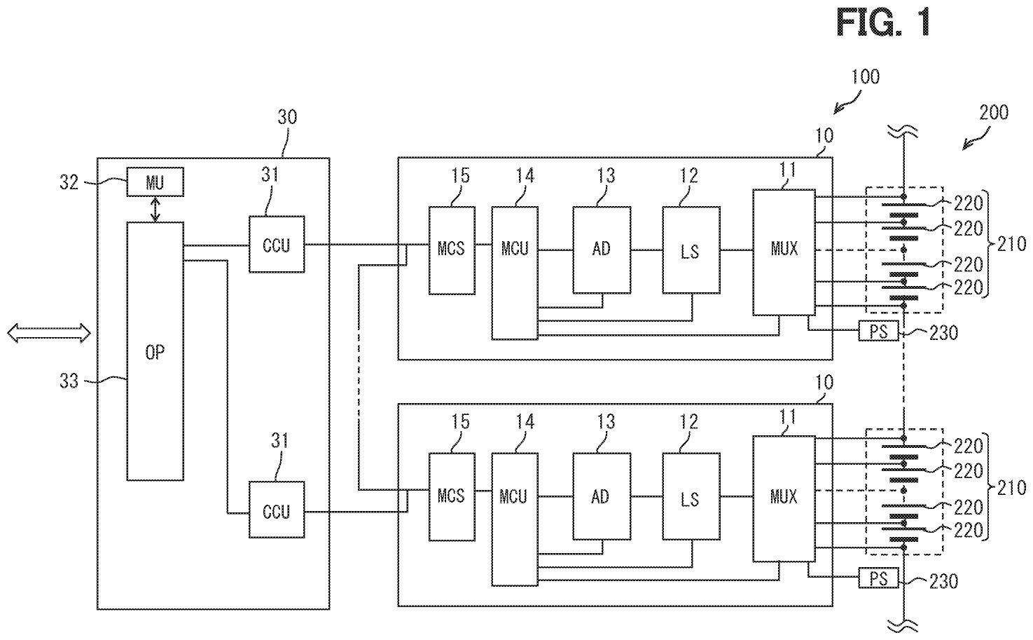

A first embodiment will be described with reference to FIGS. 1 to 6.

FIG. 1 shows a battery device 100 and an assembled battery 200. The battery device 100 and the assembled battery 200 are mounted on an electric vehicle such as a hybrid vehicle or an electric vehicle. The electric vehicles include passenger cars, buses, construction vehicles, agricultural machinery vehicles, and the like.

The battery device 100 monitors and controls the state of the assembled battery 200. The assembled battery 200 supplies electric power to various in-vehicle devices such as an electric motor that provides driving force to the electric vehicle.

(Assembled Battery)

The assembled battery 200 has a plurality of battery stacks 210. Each of the plurality of battery stacks 210 has a plurality of battery cells 220 electrically connected in series. As the battery cell 220, a secondary battery such as a lithium-ion secondary battery, a nickel-hydrogen secondary battery, or an organic radical battery can be employed. The output voltage of the battery cells 220 connected in series is the output voltage of the battery stack 210. In FIG. 1, a plurality of battery cells 220 included in one battery stack 210 are shown surrounded by dashed lines.

A plurality of battery stacks 210 are electrically connected in series or in parallel. In this embodiment, a plurality of battery stacks 210 are electrically connected in series. The output voltage of the assembled battery 200 is the sum of the output voltages of the plurality of battery stacks 210 connected in series. The power source electric power depending on this output voltage is supplied to various in-vehicle devices.

Each of the plurality of battery stacks 210 is provided with a physical quantity sensor 230 that detects the physical quantity of the battery cell 220. The physical quantities detected by the physical quantity sensor 230 include, for example, the temperature and the current of the battery cell 220.

The physical quantity detected by the physical quantity sensor 230 is used for estimating the SOC of each of the battery cell 220, the battery stack 210, and the assembled battery 200, and the like. The SOC is an abbreviation for state of charge. The SOC corresponds to the charge amount.

The SOC is reduced by supplying the above power source electric power to various in-vehicle devices. Also, the battery cell 220 self-discharges. Therefore, the SOC decreases even when the power source electric power is not supplied.

This decrease in the SOC is improved by supplying the charging power to the assembled battery 200 from a charging device such as an electric station disposed outside the vehicle, for example. The supply of charging the electric power from the charging device to the assembled battery 200 is controlled by the battery device 100. The battery device 100 controls the charging of the assembled battery 200 while transmitting and receiving a CPLT signal to and from the charging device via a wiring (not shown).

Note that the quality and environment of the plurality of battery cells 220 are not uniform. Therefore, the SOCs of the plurality of battery cells 220 may vary. This variation is improved by an equalization process, which will be described later.

<OCV, CCV, SOC>

The battery cell 220 has an internal resistance. Therefore, there is a difference of a voltage drop between the actual cell voltage according to the SOC of the battery cell 220 and the cell voltage detected by the monitor unit 10, and the voltage drop corresponds to the internal resistance and the current flowing through the battery cell 220.

Hereinafter, the actual cell voltage corresponding to the SOC of the battery cell 220 will be referred to as an open path voltage OCV as required. A cell voltage detected by the monitor unit 10 is indicated as a closed circuit voltage CCV. The internal resistance R is the resistance in the battery cell 220 and the actual current I is the current that actually flows through the battery cell 220. OCV is an abbreviation for Open Circuit Voltage. CCV is an abbreviation for Closed Circuit Voltage.

A relationship between the closed circuit voltage CCV and the open circuit voltage OCV is expressed as CCV=OCV±I×R. When the battery cell 220 is discharged, the above relationship is expressed as CCV=OCV−I×R. When the battery cell 220 is charged, the above relationship is expressed as CCV=OCV+I×R.

<Characteristics of SOC and OCV>

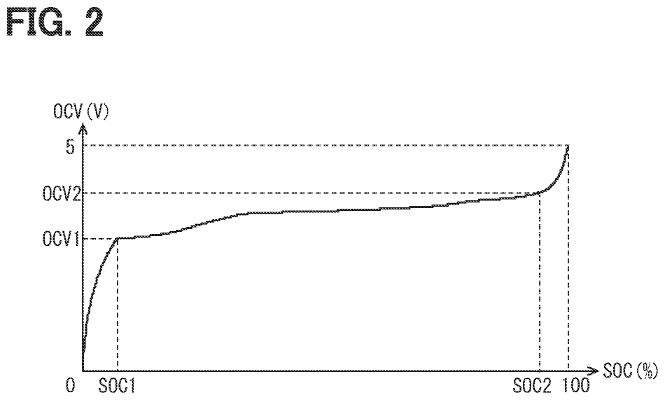

The battery cell 220 has SOC and OCV characteristics. FIG. 2 shows SOC and OCV characteristic data when the battery cell 220 is a lithium ion battery.

As shown in FIG. 2, in the over-discharge region where the SOC is close to 0%, the rate of change of OCV with respect to SOC is high. In the over-charge region where the SOC is close to 100%, the rate of change of OCV with respect to SOC is high.

On the other hand, in the charge/discharge region between the over-discharge region and the over-charge region, the rate of change of OCV with respect to SOC is low. The battery cell 220 is mainly used in this charge/discharge region. In FIG. 2, as an example, the values of the SOC and the OCV between the over-discharge region and the charge/discharge region are expressed as SOC1 and OCV1. The values of the SOC and the OCV between the charge/discharge region and the over-charge region are denoted as SOC2 and OCV2.

The characteristic data shown in FIG. 2 are temperature dependent. Therefore, the rate of change of OCV with respect to SOC changes depending on the temperature. Along with this, the values of SOC1, SOC2, OCV1 and OCV2 also change.

<Battery Device>

The battery device 100 has a monitor unit 10 and a control unit 30. The battery device 100 has the same number of monitor units 10 as the battery stacks 210. The plurality of monitor units 10 detect battery information related to the state of each of the plurality of battery stacks 210.

The control unit 30 acquires battery information detected by the multiple monitor units 10. The control unit 30 also acquires vehicle information input from various other ECUs and various sensors (not shown). When a charging device is connected to the electric vehicle, the control unit 30 acquires charging information input from the charging device. The input of the vehicle information and charging information to the control unit 30, and the output of the processing result of the control unit 30 to various ECUs, the charging device and the like are indicated by white arrows in FIG. 1.

The control unit 30 determines the state of the assembled battery 200 based on the acquired information. At the same time, the control unit 30 executes processing for the assembled battery 200. The processing for the assembled battery 200 includes, for example, charge/discharge of the assembled battery 200, equalization processing for equalizing the SOCs of the plurality of battery cells 220 included in the assembled battery 200, and the like.

<Monitor Unit>

Each of the plurality of monitor units 10 is individually provided for each of the plurality of battery stacks 210. One monitor unit 10 detects the inter-terminal voltage (i.e., the closed circuit voltage) between the positive and negative electrodes of each of the plurality of battery cells 220 included in one battery stack 210. Also, the monitor unit 10 acquires the physical quantity detected by the physical quantity sensor 230. The monitor unit 10 executes processing based on instruction signals input from the control unit 30.

As shown in FIG. 1, the monitor unit 10 has a multiplexer 11, a level shifter 12, an AD conversion unit 13, a monitor control unit 14 and a monitor communication unit 15. In the drawing, the multiplexer 11 is written as MUX. The level shifter 12 is written as LS. The AD conversion unit 13 is written as AD. The monitor control unit 14 is written as MCU. The monitor communication unit 15 is written as MCS.

The multiplexer 11 is connected to the positive and negative electrodes of each of the plurality of battery cells 220 included in one battery stack 210. As a result, the multiplexer 11 receives the closed circuit voltages of the plurality of battery cells 220.

Also, the multiplexer 11 is connected to the physical quantity sensor 230. Thereby, the physical quantity is input to the multiplexer 11.

The multiplexer 11 sequentially selects and detects a plurality of input closed circuit voltages. The multiplexer 11 sequentially outputs the detected closed circuit voltages to the level shifter 12. The multiplexer 11 also sequentially selects and detects a plurality of input physical quantities. The multiplexer 11 also sequentially outputs the detected physical quantities to the level shifter 12. The multiplexer 11 corresponds to the detection unit.

The level shifter 12 includes an operational amplifier and multiple feedback circuits connected in parallel between an input terminal and an output terminal of the operational amplifier. This feedback circuit includes a switch and a capacitor connected in series. The capacitances of the capacitors included in the multiple feedback circuits may be the same or different.

The switches of the plurality of feedback circuits of the level shifter 12 are selectively controlled to turn on and off by the monitor control unit 14. As a result, the number of capacitors connected between the input terminal and the output terminal of the operational amplifier changes. The capacitance between the input terminal and the output terminal of the operational amplifier changes. In addition, the resistance between the input terminal and the output terminal of the operational amplifier changes. As a result, the gain and the offset of the level shifter 12 are controlled.

The analog signals of the closed circuit voltage and the physical quantity whose gain and offset are adjusted is input from the level shifter 12 to the AD conversion unit 13. The AD conversion unit 13 has a clamp circuit for limiting the input range. This clamp circuit is controlled by the monitor control unit 14. The input range of the AD conversion unit 13 is thereby controlled.

By limiting the input range of the AD conversion unit 13 and adjusting the gain and the offset of the level shifter 12, the voltage range of the analog signal converted from analog to digital by the AD conversion unit 13 is controlled. The voltage ranges of the closed circuit voltage and the physical quantity that are analog-to-digital converted by the AD conversion unit 13 are controlled. As a result, the acquisition ranges of the closed circuit voltage and the physical quantity are controlled. Note that it is not necessary to particularly control the acquisition range of the physical quantity. The level shifter 12 and the AD conversion unit 13 correspond to the converter.

The AD conversion unit 13 intermittently samples continuous analog signals. Then, the AD conversion unit 13 quantizes the sampled values and converts them into discrete digital signals. Due to such conversion, there may be an error (i.e., the quantization error) between the analog signal and the digital signal.

This quantization error becomes smaller as the number of quantization bits of the AD conversion unit 13 increases. However, the number of quantization bits is fixed. Therefore, for example, when the acquisition range of the closed circuit voltage is between 0.0V and 5.0V, the resolution of the AD conversion unit 13 is the value obtained by dividing this range between 0.0V and 5.0V by the number of quantization bits.

On the other hand, for example, when the acquisition range of the closed circuit voltage is between 3.0 V and 3.5 V, which is 1/10 of the above range, the resolution of the AD conversion unit 13 is the value obtained by dividing the range between 3.0 V and 3.5 V by the number of quantization bits. In this case, the resolution of the AD conversion unit 13 is increased by about ten times. By limiting the acquisition range in this way, the detection accuracy of the closed circuit voltage is improved.

The monitor control unit 14 has a processor and a non-transitional tangible storage medium that non-transitory stores a program readable by the processor. A digital signal input from the AD conversion unit 13 and an instruction signal input from the control unit 30 are stored in this non-transitory tangible storage medium. The processor of the monitor control unit 14 controls the multiplexer 11, the level shifter 12, and the AD conversion unit 13 based on the instruction signal.

The instruction signal input to the monitor control unit 14 includes the acquisition range of the closed circuit voltage of the battery cell 220 as a detection target. The monitor control unit 14 controls the gain and the offset of the level shifter 12 when the multiplexer 11 selects the closed circuit voltage as the detection target. The monitor control unit 14 limits the input range of the AD conversion unit 13. This controls the acquisition range of the closed circuit voltage.

The digital signals of the closed circuit voltage and the physical quantity are input to the monitor communication unit 15. The monitor communication unit 15 outputs this digital signal to the control unit 30.

<Control Unit>

As shown in FIG. 1, the control unit 30 has a control communication unit 31, a storage unit 32 and a calculation unit 33. In the drawing, the control communication unit 31 is denoted as CCU. The storage unit 32 is referred to as MU. The calculation unit 33 is referred to as OP.

Various information is input to the control communication unit 31. This information includes the closed circuit voltage and the physical quantity acquired by the monitor unit 10. In addition, this information includes vehicle information and charging information. The vehicle information includes the running state of the electric vehicle and the current time. The charging information includes charging electric power.

Note that vehicle information and charging information may be input to a communication unit (not shown). And when the control unit 30 has RTC, the present time does not need to be included in the vehicle information. RTC stands for Real Time Clock.

The storage unit 32 is a non-transitory tangible storage medium that non-transitory stores programs that can be read by a computer or a processor. The storage unit 32 includes a volatile memory and a nonvolatile memory. Various information input to the control communication unit 31 and processing results of the calculation unit 33 are stored in the storage unit 32.

In addition, the storage unit 32 stores in advance programs and reference values for the calculation unit 33 to perform calculation processing. The reference values include, for example, the temperature dependence of SOC and OCV characteristic data of various secondary batteries, an equalization determination value for determining execution of equalization processing, manufacturing dates of the plurality of battery cells 220, and deterioration determination value, and the like.

The calculation unit 33 has a processor. The calculation unit 33 stores various information input to the control communication unit 31 in the storage unit 32. The calculation unit 33 executes various calculation processes based on the information stored in the storage unit 32. An electrical signal including the result of this calculation processing is output to the monitor unit 10 via the control communication unit 31. An electric signal including the result of the calculation processing is output to various ECUs via the control communication unit 31 or a communication unit (not shown).

As a specific example of the calculation process, the calculation unit 33 estimates the SOC of the battery cell 220 based on the information stored in the storage unit 32. The calculation unit 33 generates an instruction signal for instructing the operation of the monitor unit 10 based on the estimated SOC and the information stored in the storage unit 32. This instruction signal includes the acquisition range of the closed circuit voltage of the battery cell 220 as the detection target. Note that if the battery information for estimating the SOC is not stored in the storage unit 32, the calculation unit 33 sets the acquisition range of the closed circuit voltage to a possible range of the closed circuit voltage of the battery cell 220. The calculation unit 33 corresponds to the setting unit.

In addition to determining the acquisition range of the closed circuit voltage, the calculation unit 33 determines execution of an equalization process for reducing variations in the SOCs of the plurality of battery cells 220. The calculation unit 33 outputs an instruction signal including equalization processing for each of the plurality of battery stacks 210 to the monitor unit 10.

The calculation unit 33 calculates the difference between the maximum value and the minimum value of the closed circuit voltage input from the monitor unit 10. When this difference exceeds the equalization determination value, the calculation unit 33 determines to execute the equalization process. This equalization process may be performed, for example, only in the battery stack 210 in which at least one of the maximum value and the minimum value of the closed circuit voltage is detected. The equalization process may be performed on all battery stacks 210.

Although not clearly shown in the drawing, the monitor unit 10 has a plurality of switches that bridge a plurality of wires connecting the multiplexer 11 and the positive and negative electrodes of the plurality of battery cells 220, respectively. The monitor control unit 14 selectively controls the plurality of switches between the energization state and the cut-off state based on the instruction signal input from the calculation unit 33. As a result, the battery cell 220 with a relatively high SOC among the plurality of electrically connected battery cells 220 is discharged. Conversely, a battery cell 220 with relatively low SOC is charged. As a result, the SOCs of the plurality of battery cells 220 are equalized.

<Acquisition of Closed Circuit Voltage>

Due to the SOC and OCV characteristics of the battery cell 220 shown in FIG. 2, when the SOC drops due to discharge, the OCV also drops. Along with this, the closed circuit voltage CCV of the battery cell 220 also decreases. Conversely, when the SOC increases due to the supply of charging electric power from the charging device, the closed circuit voltage CCV also increases.

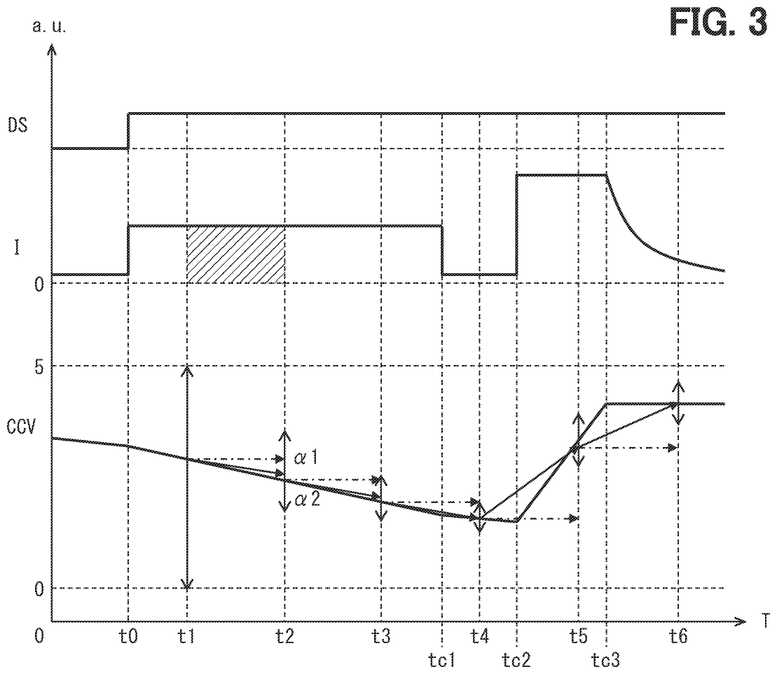

FIG. 3 shows the time change of the closed circuit voltage. The vertical axis is an arbitrary unit. The horizontal axis is time. The arbitrary unit is indicated by a. u. The time is indicated by T.

In addition to the closed circuit voltage, FIG. 3 shows the driving state of the battery device 100, the actual current flowing through the assembled battery 200, and the closed circuit voltage of one battery cell 220. The driving state of the battery device 100 is described as DS. For the sake of simplicity, the behavior of the closed circuit voltage of the battery cell 220 and the behavior of the closed circuit voltage of the assembled battery 200 shown in the drawings are assumed to be the same. In order to clarify the behavior, the drawing shows that the closed circuit voltage of the battery cell 220 changes significantly in a short time.

In the initial state at time 0, the battery device 100 is in a non-driving state. The storage unit 32 does not store battery information such as the closed circuit voltage and the physical quantity. The system main relay that controls the conduction state between the assembled battery 200 and various in-vehicle devices is in the cutoff state. Therefore, no current is substantially flowing through the assembled battery 200. The closed circuit voltage of the battery cell 220 has a value in the charge/discharge region.

Even when no current is substantially flowing through the battery cell 220, the SOC of the battery cell 220 decreases due to self-discharge. Therefore, in the initial state of time 0, the closed circuit voltage of the battery cell 220 tends to decrease in a small amount.

At time t0, the battery device 100 changes from the non-driving state to the driving state. The system main relay changes from the cutoff state to the energization state. As a result, the supply of power source electric power from the assembled battery 200 to various in-vehicle devices is started. The actual current begins to flow in the assembled battery 200. The rate of decrease in the SOC of the battery cell 220 increases. Along with this configuration, the rate of decrease in the closed circuit voltage of the battery cell 220 also increases.

At time t1, the calculation unit 33 acquires the closed circuit voltage of the battery cell 220. At this time, the battery information is not stored in the storage unit 32. Therefore, the calculation unit 33 sets the acquisition range of the closed circuit voltage at the time t1 to a possible range that the battery cell 220 can take. That is, the calculation unit 33 sets the acquisition range of the closed circuit voltage between 0.0V and 5.0V. The calculation unit 33 acquires the closed circuit voltage detected by the monitor unit 10 in the acquisition range at this time t1. Note that there is practically no time difference between time t1 and time t0. When the battery device 100 shifts from the non-drive state to the drive state, the process of detecting the closed circuit voltage is substantially started.

At time t2, the calculation unit 33 acquires the closed circuit voltage of the battery cell 220 again. At this time, it is conceivable that the calculation unit 33 determines the acquisition range of the closed circuit voltage at the time t2 based on the closed circuit voltage of the battery cell 220 acquired at the time t1. For example, if the closed circuit voltage at time t1 is 3.0V, it is conceivable to set the acquisition range of the closed circuit voltage around this 3.0V.

However, the SOC of battery cell 220 changes while time elapses from time t1 to time t2. In the example shown in FIG. 3, the amount of power indicated by hatching is discharged. It is assumed that the closed circuit voltage at time t1 and the closed circuit voltage at time t2 may be different due to this discharge.

Therefore, the calculation unit 33 calculates the median value of the acquisition range of the closed circuit voltage at the time t2 based on the closed circuit voltage acquired at the time t1 and the amount of change in the closed circuit voltage from the time t1 to the time t2. That is, the calculation unit 33 estimates the closed circuit voltage at time t2. Estimation of the closed circuit voltage at time t2 will be described in detail later. The median value of the acquisition range is a value between the upper limit value and the lower limit value of the acquisition range.

In the drawing, the tip of the dashed-dotted line arrow indicates the median value of the acquisition range of the closed circuit voltage when set based only on the acquired closed circuit voltage. The tip of the solid-line arrow indicates the median value of the acquisition range of the closed-circuit voltage when set based on the acquired closed-circuit voltage and the amount of change in the closed-circuit voltage.

As indicated by the difference in the positions of the tips of these two types of arrows, the median value of the acquisition range approaches the actual value of the closed circuit voltage of the battery cell 220 at time t2 due to the amount of change in the closed circuit voltage. As a result, the closed circuit voltage of the battery cell 220 moves away from the upper limit value and the lower limit value of the acquisition range. As a result of narrowing the acquisition range, the closed circuit voltage is suppressed from being unintentionally outside the acquisition range.

The acquisition range of the closed circuit voltage is indicated by the width of the solid double-ended arrow shown in FIG. 3. The difference between the median value and the upper limit value of the limited acquisition range is set as the upper limit range width α1. The difference between the median value and the lower limit value of the limited acquisition range is set to the lower limit range width α2. These upper limit range width α1 and lower limit range width α2 may be the same or different. The upper limit range width α1 and the lower limit range width α2 are values larger than the detection error of the closed circuit voltage. The upper limit range width α1 and the lower limit range width α2 are values smaller than half the difference between OCV1 and OCV2 shown in FIG. 2.

The magnitude relationship between the upper limit range width α1 and the lower limit range width α2 can be determined, for example, based on the time change of the closed circuit voltage. When the closed circuit voltage tends to decrease, the lower limit range width α2 can be set larger than the upper limit range width α1. Conversely, when the closed circuit voltage tends to increase, the upper limit range width α1 can be set larger than the lower limit range width α2. The magnitude of the difference between these two range widths can be set based on the time variation of the closed circuit voltage. A correction value for providing a difference between these two range widths is stored in the storage unit 32.

The calculation unit 33 sets the limited acquisition range based on the upper limit range width α1, the lower limit range width α2, and the median value of the acquisition range. In this embodiment, the calculation unit 33 sets the upper limit range width α1 and the lower limit range width α2 to be the same. Therefore, in order to simplify the notation, the upper limit range width α1 and the lower limit range width α2 are collectively referred to as the range width α. Note that when the upper limit range width α1 and the lower limit range width α2 are equal to each other in this manner, the median value of the acquisition range described above becomes the center value of the acquisition range.

The range width α is pre-stored in the storage unit 32. The range width α is a value that depends on the temperature and the current of the battery cell 220. The range width α stored in the storage unit 32 is used as the width of the acquisition range at time t2.

The calculation unit 33 determines the acquisition range at the time t2 by the calculation processing described above. The calculation unit 33 sets the acquisition range at time t2 between 2.65V and 2.93V, for example. The calculation unit 33 acquires the closed circuit voltage detected by the monitor unit 10 in the acquisition range at this time t2. When time t1 corresponds to the first detection timing, time t2 corresponds to the second detection timing.

Strictly speaking, since the battery device 100 performs a calculation process, the timing of determining the acquisition range and the timing of detecting the closed circuit voltage around time t2 are not the same. The determination timing is before the detection timing. However, the difference between these two timings is small. Therefore, these two timings are substantially regarded as the same and described.

The calculation unit 33 acquires the closed circuit voltage at the acquisition cycle. The time between time t1 and time t2 corresponds to the acquisition period. This acquisition cycle is an expected time interval in which the SOC of the battery cell 220 does not suddenly change unless the charge or discharge state of the battery cell 220 suddenly changes according to constant current charging or the like. When the acquisition cycle elapses from the time t1, the time becomes t2.

At time t3 after the acquisition period has passed from time t2, the calculation unit 33 determines the median value of the acquisition range based on the closed circuit voltage at time t2 and the amount of change in the closed circuit voltage from time t2 to time t3. Further, the calculation unit 33 calculates the difference between the closed circuit voltage obtained at time t2 and the median value of the obtained range at time t2 as an estimation error. The estimation error is a larger value than the detection error.

The calculation unit 33 calculates the range width α at the time t3 based on this estimation error and the range width α stored in the storage unit 32. When the estimation error is smaller than the predetermined value, the range width α at time t3 is smaller than the range width α stored in the storage unit 32 or the range width α at time t2. When the estimation error is larger than the predetermined value, the range width α at time t3 is larger than the range width α stored in the storage unit 32 or the range width α at time t2.

By performing the calculation processing described above, the calculation unit 33 determines the acquisition range at time t3. The calculation unit 33 sets the acquisition range at time t3 between 2.60V and 2.74V, for example. The calculation unit 33 acquires the closed circuit voltage detected by the monitor unit 10 in the acquisition range at this time t3. When time t2 corresponds to the first detection timing, time t3 corresponds to the second detection timing.

From time t3 to time tc1, the actual current decreases. Along with this configuration, the reduction rate of the closed circuit voltage is also reduced.

At time t4 after the acquisition cycle has passed from time t3, the calculation unit 33 determines the acquisition range based on the closed circuit voltage at time t3, the amount of change in the closed circuit voltage from time t3 to time t4, and the range width α that takes into account the estimation error. The calculation unit 33 sets the acquisition range at time t4 between 2.62V and 2.70V, for example. The calculation unit 33 acquires the closed circuit voltage detected by the monitor unit 10 in the acquisition range at this time t4.

Since the amount of change in closed circuit voltage between time t3 and time t4 is taken into account in this way, even if the rate of decrease in closed circuit voltage begins to decrease at time tc1 between time t3 and time t4, the closed circuit voltage acquired by the calculation unit 33 at time t4 is disposed within the acquisition range.

At tc2 elapsed from time t4, the charging device is connected to the electric vehicle. The charging device charges the assembled battery 200 with a constant current. As a result, the actual current rises sharply. The calculation unit 33 acquires such information from vehicle information or charging information.

At time t5 after the acquisition cycle has passed from time t4, the calculation unit 33 determines the acquisition range based on the closed circuit voltage at time t4, the amount of change in the closed circuit voltage from time t4 to time t5, and the range width α that takes into account the estimation error. The calculation unit 33 acquires the closed circuit voltage detected by the monitor unit 10 in the acquisition range at this time t5.

Since the amount of change in closed circuit voltage between time t4 and time t5 is taken into account in this way, even if the closed circuit voltage begins to rapidly increase at time tc2 between time t4 and time t5, the closed circuit voltage acquired by the calculation unit 33 at time t5 is disposed within the acquisition range.

Note that when constant current charging is performed in this way, the change rate of the closed circuit voltage per unit time increases. Therefore, the range width α at time t5 may be amplified and corrected more than the range width α at time t4. Alternatively, the range width α during constant current charging may be stored in the storage unit 32. This range width α may be used at time t5. The calculation unit 33 sets the acquisition range at time t5 between 3.25V and 3.75V, for example.

When the time t5 changes to the time tc3, the output voltage of the assembled battery 200 reaches the target voltage. When detecting this, the calculation unit 33 terminates the constant current charging by the charging device. The calculation unit 33 causes the charging device to perform the constant voltage charging. Note that the calculation unit 33 may perform forced charging instead of constant voltage charging after completion of constant current charging.

The constant-current charging and the constant-voltage charging described above may differ in the amount of supplied current. The constant-current charging has a larger current supply than the constant-voltage charging.

As described above, there is a difference of the voltage drop of I×R between the closed circuit voltage CCV and the open circuit voltage OCV. During the charging, an expression of “CCV=OCV+I×R” is established. Therefore, even if the maximum output voltage of the assembled battery 200 is detected as the closed circuit voltage CCV, the open circuit voltage OCV does not reach the maximum output voltage. The SOC of the assembled battery 200 has not reached the full charge capacity.

The above target voltage is a value based on the maximum output voltage of the assembled battery 200. When the calculation unit 33 determines that the closed circuit voltage of the assembled battery 200 has reached the target voltage, it causes the charging device to perform the constant voltage charging. In the constant voltage charging, the charging power is supplied to the assembled battery 200 while maintaining the closed circuit voltage detected in the assembled battery 200 at the target voltage in order to bring the SOC of the assembled battery 200 closer to the full charge amount with avoiding over-charging. The target voltage and the maximum output voltage are stored in advance in the storage unit 32.

At time t6 after the acquisition cycle has elapsed from time t5, the calculation unit 33 acquires the closed circuit voltage of the battery cell 220 detected by the monitoring unit 10 in the acquisition range determined based on the target voltage and the range width α during the constant voltage charging. The calculation unit 33 sets the acquisition range at time t6 between 4.23V and 4.26V, for example.

After time t6, it is expected that the target voltage will be obtained as long as the constant voltage charging continues. In this case, the calculation unit 33 continues to acquire the closed circuit voltage of the battery cell 220 within the acquisition range determined based on the target voltage and the range width α during the constant voltage charging. Alternatively, the calculation unit 33 may stop acquiring the closed circuit voltage. The range width α during the constant-voltage charging is, for example, a smaller value than the range width α used at time t2. The range width α during the constant voltage charging is stored in the storage unit 32.

<Constant Voltage Drive>

If the SOC of the assembled battery 200 is excessively reduced or the electric motor of the electric vehicle malfunctions, the electric vehicle performs constant voltage drive with limited driving. At this time, the voltage of the power supply output from the assembled battery 200 is limited. The voltage of the power supply is kept at a constant value, for example. Therefore, it may be expected that the closed circuit voltage of the battery cell 220 is maintained at a predetermined voltage.

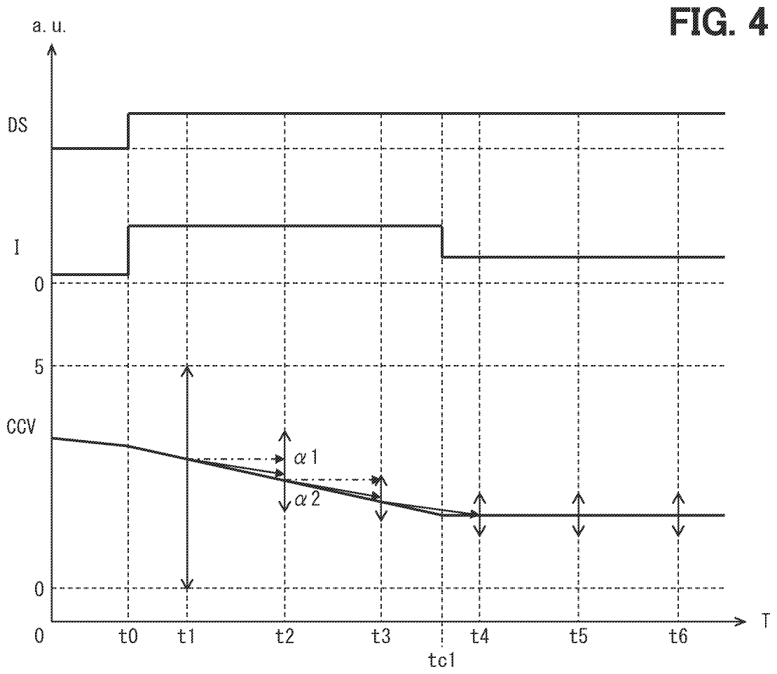

In the example shown in FIG. 4, at time tc1 between time t3 and time t4, the electric vehicle transitions from unrestricted normal drive to restricted constant voltage drive. In this case, the calculation unit 33 acquires the closed circuit voltage of the battery cell 220 in the acquisition range determined based on the predetermined voltage and the range width α during constant voltage driving at time t4. The calculation unit 33 sets the acquisition range at time t4 between 2.47V and 2.53V, for example.

After time t4, it may be expected that the predetermined voltage will be obtained as long as the constant voltage drive continues. In this case, the calculation unit 33 continues to acquire the closed circuit voltage of the battery cell 220 within the acquisition range determined based on the predetermined voltage and the range width α during the constant voltage drive. Alternatively, the calculation unit 33 may stop acquiring the closed circuit voltage.

The range width α during constant voltage drive is smaller than the range width α during normal drive. The range width α during the constant voltage drive is stored in the storage unit 32. Note that when the electric vehicle changes from a running state to a stopped state, there is a possibility that the closed circuit voltage may suddenly change in a short period of time. The value of the range width α may be set so as to avoid the closed-circuit voltage falling outside the acquisition range due to such a sudden change.

<Estimation of Closed Circuit Voltage>

As described above, the calculation unit 33 calculates the median value of the acquisition range when calculating the acquisition range of the closed circuit voltage. That is, the calculation unit 33 estimates the closed circuit voltage at the time of acquisition. For example, at time t2 shown in FIG. 3, the calculation unit 33 estimates the closed circuit voltage at time t2 based on the closed circuit voltage obtained at time t1 and the amount of change in the closed circuit voltage from time t1 to time t2.

The amount of change in the closed circuit voltage from time t1 to time t2 is calculated based on the charge/discharge history between time t1 and time t2, the temperature between time t1 and time t2, and the temperature dependence of the SOC and OCV characteristic data. The charge/discharge history corresponds to the charge/discharge amount.

The charge/discharge history between time t1 and time t2 is calculated, for example, based on the time difference between time t1 and time t2 and the current between time t1 and time t2. The charge/discharge history between time t1 and time t2 is calculated as an integrated value of current between time t1 and time t2. Note that the current between time t1 and time t2 is estimated by, for example, the addition average value of the current at time t1 and the current at time t2.

The temperature between time t1 and time t2 is estimated by, for example, the addition average value of the temperature at time t1 and the temperature at time t2. The calculation unit 33 reads the SOC and OCV characteristic data of this temperature from the storage unit 32. Then, the calculation unit 33 calculates the amount of change in the closed circuit voltage from time t1 to time t2 based on the read SOC and OCV characteristic data and the calculated charge/discharge history between time t1 and time t2. The current, the temperature, and the characteristic data are included in the variation.

Here, the calculation unit 33 reads the SOC and OCV characteristic data of the battery cell 220 from the storage unit 32 among the SOC and OCV characteristic data of various secondary batteries. When the battery cell 220 is a lithium-ion secondary battery, the calculation unit 33 reads the SOC and OCV characteristic data of the lithium-ion secondary battery from the storage unit 32.

The calculation unit 33 estimates the time-related deterioration of the battery cell 220 at the time t2, for example, based on the difference between the date of manufacture of the battery cell 220 and the time t2 stored in the storage unit 32 and the deterioration determination value. The calculation unit 33 may estimate the internal resistance of the battery cell 220 at time t2 based on the time-related deterioration of the battery cell 220 and the temperature at time t2. The calculation unit 33 may calculate the voltage drop occurring in the battery cell 220 at the time t2 based on the internal resistance and the current at the time t2. The calculation unit 33 may also take this voltage drop into account to estimate the closed circuit voltage at time t2. When estimating the internal resistance in this way, the range width α may be set in consideration of the internal resistance.

Further, the calculation unit 33 may estimate the amount of change in the closed circuit voltage from time t1 to time t2 based on the equivalent circuit model or chemical reaction model of the battery cell 220 and the current and the temperature of the battery cell 220.

Further, as an example, the storage unit 32 may store a discharge value and a charge value for roughly estimating the amount of change in the closed circuit voltage described above. The amount of change in the closed circuit voltage may be determined by multiplying the predetermined discharge value by the time difference between time t1 and time t2. The amount of change in the closed circuit voltage may be determined by multiplying the predetermined charge value by the time difference between time t1 and time t2. In this modification, the discharge value and the charge value are included in the charge/discharge amount.

<Voltage Detection Processing>

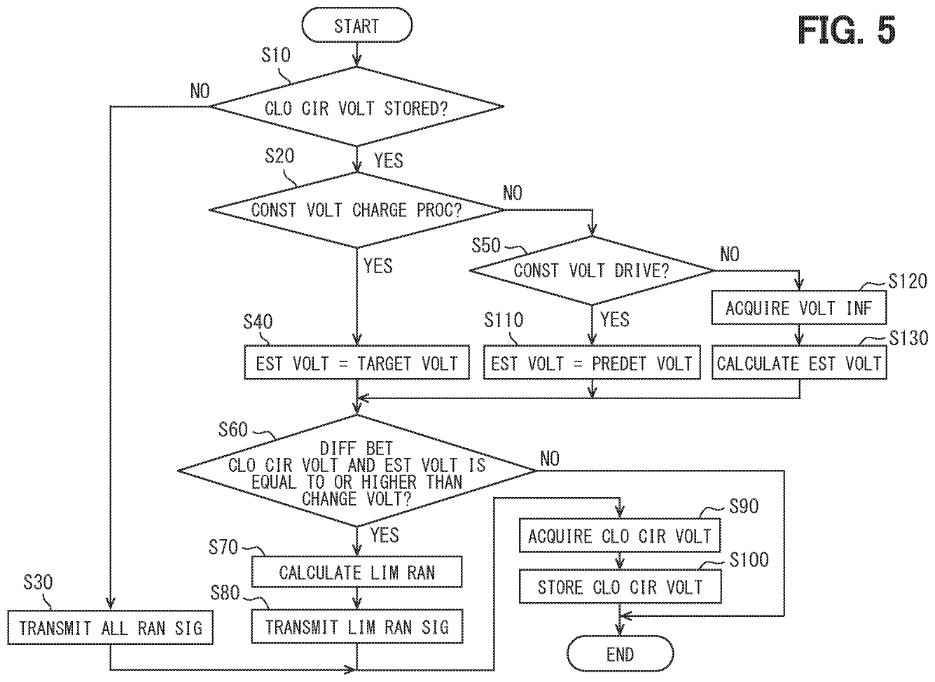

Next, the voltage detection processing of the calculation unit 33 will be described with reference to FIG. 5. The calculation unit 33 executes this voltage detection process as a cycle task. The execution interval of this voltage detection process corresponds to the acquisition period described above.

In step S10, the calculation unit 33 determines whether or not the closed circuit voltage is stored in the storage unit 32. When the closed circuit voltage is stored in the storage unit 32, the calculation unit 33 proceeds to step S20. If the closed circuit voltage is not stored in the storage unit 32, the calculation unit 33 proceeds to step S30.

When proceeding to step S20, the calculation unit 33 determines whether or not the constant voltage charging process is being performed. If the constant voltage charging process is being executed, the calculation unit 33 proceeds to step S40. If the constant voltage charging process is not being executed, the calculation unit 33 proceeds to step S50.

When proceeding to step S40, the calculation unit 33 sets the closed circuit voltage (i.e., the estimated voltage) expected to be detected by the monitoring unit 10 as the target voltage. In other words, the calculation unit 33 sets the closed circuit voltage used for the acquisition range of the closed circuit voltage as the target voltage. After this process, in the calculation unit 33, the process proceeds to step S60.

When proceeding to step S60, the calculation unit 33 calculates the difference value between the estimated voltage and the closed circuit voltage stored in the storage unit 32. The calculation unit 33 determines whether or not this difference value is greater than or equal to the change voltage stored in the storage unit 32. If the difference value is greater than or equal to the change voltage, the calculation section 33 proceeds to step S70. If the difference value is smaller than the change voltage, the calculation unit 33 terminates the voltage detection process.

When the process proceeds to step S70, the calculation unit 33 sets a limited acquisition range of the closed circuit voltage based on the estimated voltage and various information stored in the storage unit 32. After this process, in the calculation unit 33, the process proceeds to step S80.

When the process proceeds to step S70 through step S40, the calculation unit 33 reads the range width α during constant voltage charging from the storage unit 32. The calculation unit 33 calculates the acquisition range of the closed circuit voltage based on the range width α and the target voltage. The calculation unit 33 stores this acquisition range in the storage unit 32. Then, in the calculation unit 33, the process proceeds to step S80.

When proceeding to step S80, the calculation unit 33 transmits an instruction signal including the acquisition range calculated in step S70 to the monitoring unit 10 as a limited range signal. After this process, in the calculation unit 33, the process proceeds to step S90.

When proceeding to step S90, the calculation unit 33 acquires the closed circuit voltage detected by the monitor unit 10. After this process, in the calculation unit 33, the process proceeds to step S100.

When proceeding to step S100, the calculation unit 33 stores the acquired closed circuit voltage in the storage unit 32. Also, at this time, the calculation unit 33 stores the acquisition range in the storage unit 32. Then, the calculation unit 33 terminates the voltage detection process.

Retracing the flow, when it is determined in step S20 that the constant voltage charging process is not being executed and the process proceeds to step S50, the calculation unit 33 determines whether or not the electric vehicle is in the constant voltage drive. That is, the calculation unit 33 determines whether or not the closed circuit voltage of the battery cell 220 is the predetermined voltage. In the case of the constant voltage drive, the calculation unit 33 proceeds to step S110. If it is not the constant voltage drive, the calculation unit 33 proceeds to step S120.

When proceeding to step S110, the calculation unit 33 sets the estimated voltage to a predetermined voltage. In other words, the calculation unit 33 sets the closed circuit voltage used for calculating the acquisition range of the closed circuit voltage to a predetermined voltage. After this process, in the calculation unit 33, the process proceeds to step S60.

When the process proceeds to step S110 through step S40, the calculation unit 33 reads the range width α during the constant voltage drive from the storage unit 32. The calculation unit 33 sets the acquisition range of the closed circuit voltage based on the range width α and the predetermined voltage.

Retracing the flow, when it is determined in step S50 that the constant voltage drive is not performed and the process proceeds to step S120, the calculation unit 33 acquires various information for calculating the estimated voltage. This information includes the closed circuit voltage, the acquisition cycle, the current, the temperature, the SOC and OCV characteristic data, and the like stored in the storage unit 32. After this process, in the calculation unit 33, the process proceeds to step S130.

When proceeding to step S130, the calculation unit 33 calculates the estimated voltage based on the various information acquired in step S120. After this process, in the calculation unit 33, the process proceeds to step S60.

When the process proceeds to step S70 through step S130, the calculation unit 33 reads the range width α from the storage unit 32. The calculation unit 33 sets the acquisition range of the closed circuit voltage based on the range width α and the estimated voltage.

As described above, the voltage detection process is a cycle task. If step S80 has been performed in the previous voltage detection process, in step S70 the calculation unit 33 calculates the estimated error by subtracting the closed circuit voltage stored in the storage unit 32 from the estimated voltage. The calculation unit 33 sets the acquisition range of the closed circuit voltage based on the range width α and the estimated voltage. Unlike this, when step S30 has been executed in the previous voltage detection process, the calculation unit 33 stops calculating the estimated error. In this case, the calculation unit 33 sets the acquisition range of the closed circuit voltage based on the range width α and the estimated voltage.

Returning the flow, when it is determined in step S10 that the closed circuit voltage is not stored in the storage unit 32 and the process proceeds to step S30, the calculation unit 33 transmits the instruction signal including the possible acquisition range of the closed circuit voltage to the monitor unit 10 as a full range signal. After this process, in the calculation unit 33, the process proceeds to step S90.

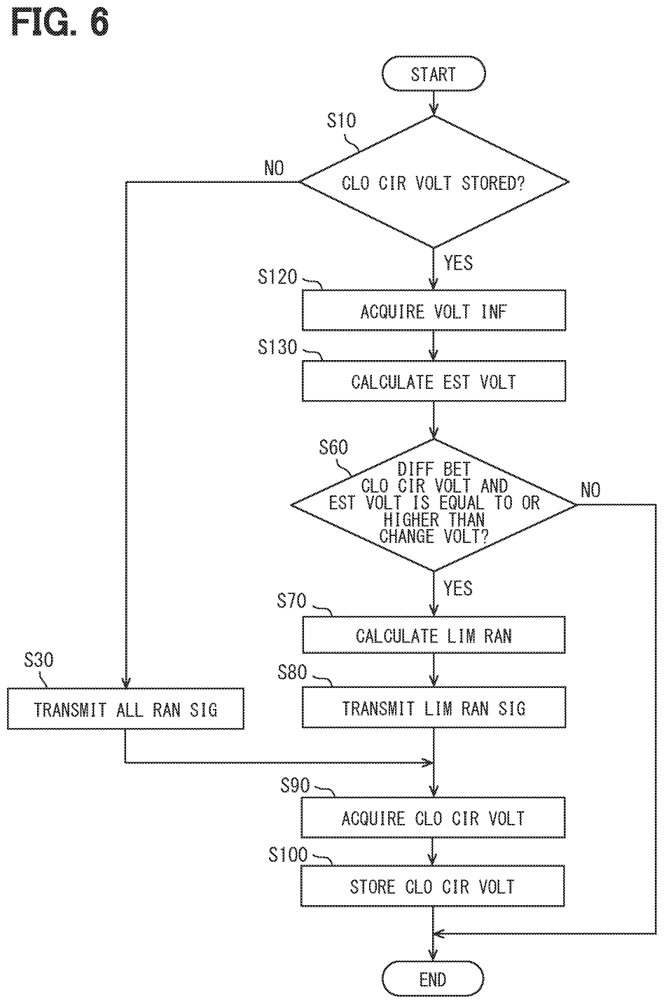

Note that the calculation unit 33 may not execute steps S20, S40, S50, and S110 shown in FIG. 5. In this case, as shown in FIG. 6, when it is determined in step S10 that the closed circuit voltage is stored in the storage unit 32, the calculation unit 33 proceeds to step S120.

<Operations and Effects>

As described above, the calculation unit 33 sets the acquisition range of the closed circuit voltage based on the past closed circuit voltage stored in the storage unit 32 and the amount of change in the closed circuit voltage of the battery cell 220 until the closed circuit voltage is acquired again.

For example, the calculation unit 33 changes the acquisition range of the closed circuit voltage from a possible acquisition range of 0.0V to 5.0V to a limited acquisition range of 2.65V to 2.93V. In this limited acquisition range, the analog closed circuit voltage is converted into a digital signal by the AD conversion unit 13. This reduces the quantization error of the AD conversion unit 13. As a result, the detection accuracy of the closed circuit voltage is improved.

In addition, as described above, the calculation unit 33 sets the acquisition range of the closed circuit voltage in consideration of the amount of change in the closed circuit voltage of the battery cell 220 until the closed circuit voltage is acquired again. Therefore, the closed circuit voltage is suppressed from being out of the acquisition range.

The range width α of the acquisition range is determined in consideration of the difference (i.e., the estimation error) between the past closed circuit voltage stored in the storage unit 32 and the median value of the acquisition range of the closed circuit voltage set when the closed circuit voltage is detected. According to this, it is effectively suppressed that the closed circuit voltage is out of the acquisition range.

If the estimated error is smaller than the predetermined value, the calculator 33 narrows the range width α. This narrows the acquisition range of the closed circuit voltage. Detection accuracy of the closed circuit voltage is improved.

If the difference value between the estimated voltage and the closed circuit voltage stored in the storage unit 32 is smaller than the change voltage, the calculation unit 33 stops setting a new acquisition range. According to this, the calculation processing in the calculation unit 33 is simplified.

### Second Embodiment

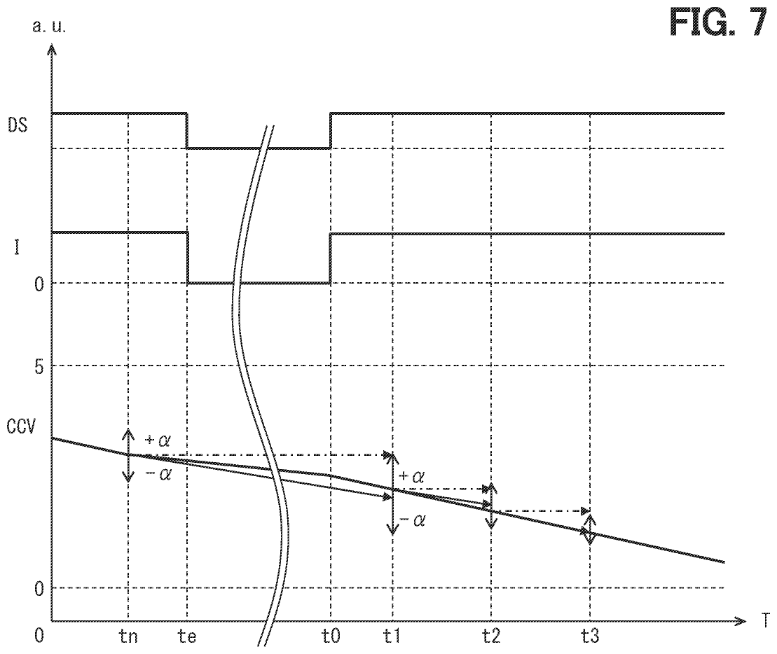

Next, a second embodiment will be described with reference to FIG. 7.

In the first embodiment, as described with reference to FIG. 3, the example in which battery information is not stored in the storage unit 32 when the calculation unit 33 switches from the non-drive state to the drive state is shown. Alternatively, the battery information may be stored in the storage unit 32 when the calculation unit 33 switches from the non-drive state to the drive state. Then, the calculation unit 33 may determine the acquisition range of the closed circuit voltage when the non-drive state is switched to the drive state based on the battery information stored in the storage unit 32 and the amount of change in the closed circuit voltage.

For example, in the initial state of time 0 shown in FIG. 7, the battery device 100 is in a drive state. The storage unit 32 stores the battery information such as the closed circuit voltage and the physical quantity. The system main relay is energized. Therefore, current flows through the assembled battery 200. The closed circuit voltage is the value in the charge/discharge region.

At time tn, the calculation unit 33 determines the acquisition range. The calculation unit 33 acquires the closed circuit voltage and the physical quantity detected by the monitoring unit 10 in the acquisition range at this time tn. The calculation unit 33 stores the closed circuit voltage and the physical quantity detected at the time tn in the storage unit 32. At the same time, the calculation unit 33 stores the acquisition range determined at the time tn in the storage unit 32. The battery information at time tn is stored in the storage unit 32.

From time tn to time te, the battery device 100 changes from the drive state to the non-drive state. At this time, the battery information stored in the storage unit 32 is saved. The system main relay changes from the energization state to the cut off state. The electric current does not substantially flow through the assembled battery 200. After that, the SOC of the battery cell 220 gradually decreases due to self-discharge. At the same time, the closed circuit voltage is also gradually reduced.

At time t0, the battery device 100 changes from the non-driving state to the driving state. The system main relay changes from the cutoff state to the energization state. The current begins to flow in the assembled battery 200. The reduction rates of the SOC and the closed circuit voltage of the battery cell 220 increase.

At time t1, the calculation unit 33 calculates the median value of the acquisition range of the closed circuit voltage at time t1 based on the closed circuit voltage stored in the storage unit 32 and the amount of change in the closed circuit voltage from time tn at which the closed circuit voltage was stored to time t1.

As described in the first embodiment, the amount of change in the closed circuit voltage is calculated based on the charge/discharge history between time tn and time t1, the temperature between time tn and time t1, and the temperature dependence of the characteristic data of the SOC and the OCV. The amount of change in the closed circuit voltage may be calculated in consideration of the internal resistance of the battery cell 220. Also, the amount of change in the closed circuit voltage may be calculated based on the equivalent circuit model or chemical reaction model of the battery cell 220 and the current and the temperature of the battery cell 220.

Here, as described above, the voltage detection process is executed in cycle tasks. The acquisition cycle is set in units of several microseconds to several seconds. Note that there is practically no time difference between time t1 and time t0.

Therefore, the time difference between the time tn and the time te, which is shorter than the acquisition cycle, is considered to be negligibly short compared to the time difference between the time te and the time t0 when the battery device 100 is in the non-drive state. Similarly, the time difference between time t0 and time t1 with no substantial time difference is negligibly small compared to the time difference between time te and time t0 when battery device 100 is in the non-drive state.

Between time tn and time te and between time t0 and time t1, which can be regarded as negligibly short compared to the time difference between this time te and time t0, the battery cell 220 is actively discharged effectively. The battery cell 220 self-discharges during the time interval between time te and time t0.

Thus, between time tn and time t1, the time during which the battery cell 220 actively discharges is negligibly short compared to the time during which the battery cell 220 self-discharges. Therefore, the amount of change in closed circuit voltage from time tn to time t1 can be estimated based on the amount of self-discharge of the battery cell 220 per unit time and the time difference between time tn and time t1. The self-discharge amount of the battery cell 220 per unit time can be estimated based on the type of the battery cell 220, the temperature, the temperature dependency of SOC and OCV characteristic data, the current, the degree of deterioration, and the like.

By executing such calculation processing, it is possible to improve the detection accuracy of the closed circuit voltage even when the battery device 100 transitions from the non-drive state to the drive state.

In the present embodiment, an example is shown in which the battery device 100 does not detect the closed circuit voltage at the time te when the battery device 100 changes from the drive state to the non-drive state. Alternatively, the battery device 100 may detect the closed circuit voltage at this time te.

Note that when the electric vehicle is in a non-drive state, the calculation unit 33 is periodically activated to determine whether or not the equalization process should be performed. When the calculation unit 33 performs the equalization process while the electric vehicle is in the non-drive state, the calculation unit 33 acquires the charge/discharge amounts of the plurality of battery cells 220 associated with the equalization process and stores them in the storage unit 32. Then, when the electric vehicle shifts from the non-drive state to the drive state, the calculation unit 33 determines the acquisition range of the closed circuit voltage based on the various information stored in the storage unit 32 and the physical quantity acquired at this time.

(Other Modifications)

In this embodiment, an example is shown in which one control unit 30 is provided for a plurality of monitor units 10. Alternatively, a configuration in which a plurality of controllers 30 are provided individually for a plurality of monitor units 10 may also be adopted.

In this embodiment, an example of setting the acquisition range of the closed circuit voltage of each of the plurality of battery cells 220 has been described. Alternatively, it may be also possible to employ a configuration in which the acquisition range of the closed circuit voltage of each of the plurality of battery stack 210 is set. It may be also possible to employ a configuration in which a common closed circuit voltage acquisition range is set for each of the plurality of battery cells 220 included in one battery stack 210. In such a modification, the assembled battery 200 has at least two battery stacks 210.

In this embodiment, an example is shown in which each of the plurality of battery cells 220 is the same type of secondary battery. Alternatively, a part of the plurality of battery cells 220 may be different secondary batteries among the plurality of battery cells 220. For example, some battery stacks 210 among the plurality of battery stacks 210 may include first type battery cells 220, and the remaining battery stacks 210 may include second type battery cells 220 different from the first type. As the battery cells 220 of different types, for example, the battery cells 220 having the same internal configuration and external configuration but different composition materials for the positive and negative electrodes can be employed.

In the case of such a modification, when estimating the amount of change in the closed circuit voltage, the calculation unit 33 reads the SOC and OCV characteristic data of the first type battery cell 220 and the SOC and OCV characteristic data of the second type battery cell 220 from the storage unit 32.

Although the present disclosure has been described in accordance with the examples, it is understood that the present disclosure is not limited to such examples or structures. To the contrary, the present disclosure is intended to cover various modification and equivalent arrangements. In addition, while various combinations and modes are described in the present disclosure, other combinations and modes including only one element, more elements, or less elements therein are also within the scope and spirit of the present disclosure.

The controllers and methods described in the present disclosure may be implemented by a special purpose computer created by configuring a memory and a processor programmed to execute one or more particular functions embodied in computer programs. Alternatively, the controllers and methods described in the present disclosure may be implemented by a special purpose computer created by configuring a processor provided by one or more special purpose hardware logic circuits. Alternatively, the controllers and methods described in the present disclosure may be implemented by one or more special purpose computers created by configuring a combination of a memory and a processor programmed to execute one or more particular functions and a processor provided by one or more hardware logic circuits. The computer programs may be stored, as instructions being executed by a computer, in a tangible non-transitory computer-readable medium.

It is noted that a flowchart or the processing of the flowchart in the present application includes sections (also referred to as steps), each of which is represented, for instance, as S10. Further, each section can be divided into several sub-sections while several sections can be combined into a single section. Furthermore, each of thus configured sections can be also referred to as a device, module, or means.

What is claimed is:

1. A battery device comprising:
a storage unit that stores battery information including a closed circuit voltage of a plurality of battery cells electrically connected to each other and a change amount in the closed circuit voltage;
a setting unit that sets an acquisition range of the closed circuit voltage based on the battery information;
a detection unit that detects the closed circuit voltage; and
a conversion unit that converts the closed circuit voltage detected by the detection unit into a digital signal within the acquisition range set by the setting unit.

2. The battery device according to claim 1, wherein:
the change amount includes a charge and discharge amount of the battery cells during a period from a first detection timing at which the closed circuit voltage stored in the storage unit is detected by the detection unit to just before a second detection timing at which the closed circuit voltage is newly detected by the detection unit.

3. The battery device according to claim 2, wherein:
the setting unit sets a median value of the acquisition range at the second detection timing based on the closed circuit voltage and the change amount stored in the storage unit.

4. The battery device according to claim 3, wherein:
the setting unit sets a width of the acquisition range at the second detection timing based on a difference between the closed circuit voltage stored in the storage unit and the median value of the acquisition range at the first detection timing.

5. The battery device according to claim 3, wherein:
the setting unit sets a magnitude relationship between an upper limit range width and a lower limit range width based on the change amount;
the upper limit range width is a difference between the median value of the acquisition range at the second detection timing and an upper limit value of the acquisition range at the second detection timing; and
the lower limit range width is a difference between the median value of the acquisition range at the second detection timing and a lower limit value of the acquisition range at the second detection timing.

6. The battery device according to claim 5, wherein:
the setting unit sets the lower limit range width larger than the upper limit range width when the change amount tends to decrease; and the setting unit sets the upper limit range width larger than the lower limit range width when the change amount tends to increase.

7. The battery device according to claim 3, wherein:
the setting unit determines to newly set the acquisition range at the second detection timing when a difference value between the median value of the acquisition range at the second detection timing and the closed circuit voltage stored in the storage unit is equal to or greater than a change voltage; and
the setting unit stops newly setting the acquisition range at the second detection timing when the difference value is smaller than the change voltage.

8. The battery device according to claim 3, wherein:
when the closed circuit voltage is a predetermined voltage, the setting unit sets the median value of the acquisition range at the second detection timing to the predetermined voltage.

9. The battery device according to claim 2, wherein:
the first detection timing is before the setting unit switches from a drive state to a non-drive state; and the second detection timing is after the setting unit switches from the non-drive state to the drive state.

10. The battery device according to claim 9, wherein:
the change amount includes an amount of self-discharge of the battery cells from the first detection timing to the second detection timing.
